(19) United States
(12) Patent Application Publication
(10) Pub. No.: US 2010/0117109 A1
(43) Pub. Date: May 13, 2010

(54) Light emitting element

(75) Inventor: Tsunehiro Unno, Hitachi (JP)

Correspondence Address: DANIEL D BENTLEY, 624 S HYDE PARK, DENISON, TX, 75020, US

(73) Assignee: HITACHI CABLE, LTD., Tokyo (JP)

(21) Appl. No.: 12/461,007

(22) Filed: Jul. 29, 2009

(30) Foreign Application Priority Data
Nov. 10, 2008 (JP) 2008-287314

(51) Int. Cl. H01L 33/00

(52) U.S. Cl. 257/98; 257/E33.067

(57) ABSTRACT

A light emitting element includes a semiconductor stacked structure including a first semiconductor layer of first conductivity type, a second semiconductor layer of second conductivity type different from the first conductivity type and an active layer sandwiched between the first semiconductor layer and the second semiconductor layer. The light emitting element further includes a plurality of convex portions formed on one surface of the semiconductor stacked structure, and an embedded part for transmitting a light emitted from the active layer and reducing stress generated in the plurality of convex portions, the embedded part being formed between two adjacent convex portions of the plurality of convex portions.

The present application is based on Japanese patent application No. 2008-287314 filed on Nov. 10, 2008, the entire contents of which are incorporated herein by reference.

### BACKGROUND OF THE INVENTION

1. Field of the Invention

This invention relates to a light emitting element. In particular, this invention relates to a light emitting element having a high brightness.

2. Description of the Related Art

Conventionally, a light emitting element is known that includes a light emitting layer, a light transmitting layer disposed on the light emitting layer so as to have a textured surface on a light extraction surface, and a smoothing layer made of silicon and disposed on the light transmitting layer so as to have no void between the light transmitting layer and the smoothing layer and to cover the textured surface, wherein the smoothing layer has a lower refractive index than that of the light transmitting layer and the exposed surface of smoothing layer is smoother than the textured surface (for example, refer to Patent Literature 1).

The light emitting element described in Patent Literature 1 includes the light transmitting layer which has the textured surface on the light extraction surface and the smoothing layer made of silicon which covers the textured surface, and then air bubbles are not easily to be trapped between the light emitting element and a sealing material for sealing the light emitting element, so that the element can prevent the air bubbles from forming voids in the sealing material.

Patent Literature 1: JP-A-2007-266571

However, in case of the light emitting element described in Patent Literature 1, if silicon is embedded in the textured surface for enhancing a light extraction efficiency, namely, a surface having concave and convex portions, a breaking may occur in the concave and convex portions due to a thermal shock applied to the light emitting element. If the concave and convex portions are broken, the light extraction efficiency of the light emitting element may be reduced.

### SUMMARY OF THE INVENTION

Therefore, it is an object of the invention to solve the above-mentioned problem and provide a light emitting element that has a high brightness.
(1) According to one embodiment of the invention, a light emitting element comprises:

a semiconductor stacked structure comprising a first semiconductor layer of first conductivity type, a second semiconductor layer of second conductivity type different from the first conductivity type and an active layer sandwiched between the first semiconductor layer and the second semiconductor layer;

a plurality of convex portions formed on one surface of the semiconductor stacked structure; and

an embedded part for transmitting a light emitted from the active layer and reducing stress generated in the plurality of convex portions, the embedded part being formed between two adjacent convex portions of the plurality of convex portions.

In the above embodiment (1), the following modifications and changes can be made.

(i) The plurality of convex portions comprise a cross sectional structure that gradually narrows in a direction from the active layer to the one surface of the semiconductor stacked structure.

(ii) The embedded part comprises a material with a refractive index between that of the plurality of convex portions and that of a resin for covering the light emitting element.

(iii) The embedded part comprises a material with a linear expansion coefficient of not more than 1×10⁻⁵/K.

(iv) The plurality of convex portions comprise, in a cross section, a length of a horizontal part thereof along a horizontal plane parallel to the active layer is not more than a length of a height part thereof in a direction perpendicular to the horizontal plane.

(v) The embedded part comprises a plurality of stacked materials with linear expansion coefficients different from each other.

(vi) The embedded part is formed to cover a tip portion of the plurality of convex portions.

(vii) The plurality of convex portions comprise a trapezoidal form in a cross section.

(viii) The semiconductor stacked structure further comprises a sidewall layer formed at least on a side face of the active layer.

### Points of the Invention

According one embodiment of the invention, a light emitting element is constructed such that plural convex portions are formed on the light extraction surface, a concave portion formed between two adjacent ones is embedded with a material with a linear expansion coefficient close to that of a semiconductor material composing the convex portions. Thereby, even when thermal shock is applied to a light emitting device produced by sealing the light emitting element with a resin, stress occurred in the convex portions can be reduced. Thus, the convex portions are suppressed from being cracked or broken so as not to lower the light extraction efficiency of the light emitting device.

### BRIEF DESCRIPTION OF THE DRAWINGS

The preferred embodiments according to the invention will be explained below referring to the drawings.

FIG. 1A is a schematic cross-sectional view showing a light emitting element in a first preferred embodiment according to the invention;

FIGS. 1B and 1C are each schematic perspective views showing a convex portion in the first embodiment according to the invention;

FIG. 1D is a cross-sectional view cut along the line A-A in FIGS. 1B and 1C;

FIGS. 2A to 2Q are each schematic cross-sectional views showing the flow of a production method of a light emitting element in the first embodiment according to the invention;

FIG. 3 is a schematic cross-sectional view showing a light emitting device mounting the light emitting element in the first embodiment according to the invention;

FIGS. 4A and 4B are schematic perspective views showing convex portions in modification of the first embodiment according to the invention;

FIG. 4C is a cross-sectional view cut along the line B-B in FIGS. 4A and 4B;

FIG. 5 is a schematic cross-sectional view showing a part of a light emitting element in a second preferred embodiment according to the invention;

FIG. 6 is a schematic cross-sectional view showing a part of a light emitting element in a third preferred embodiment according to the invention;

FIGS. 7A and 7B are each schematic cross-sectional views showing a part of light emitting elements in modification of the third embodiment according to the invention; and

FIG. 8 is a schematic cross-sectional view showing a light emitting element in a fourth preferred embodiment according to the invention.

### DETAILED DESCRIPTION OF THE PREFERRED EMBODIMENTS

### First Embodiment

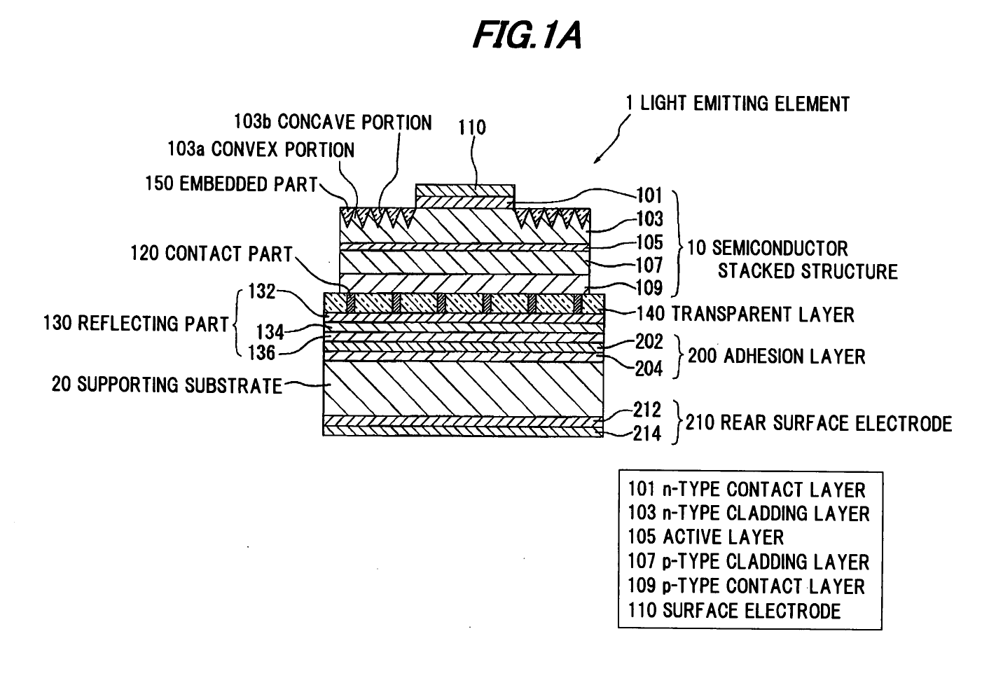

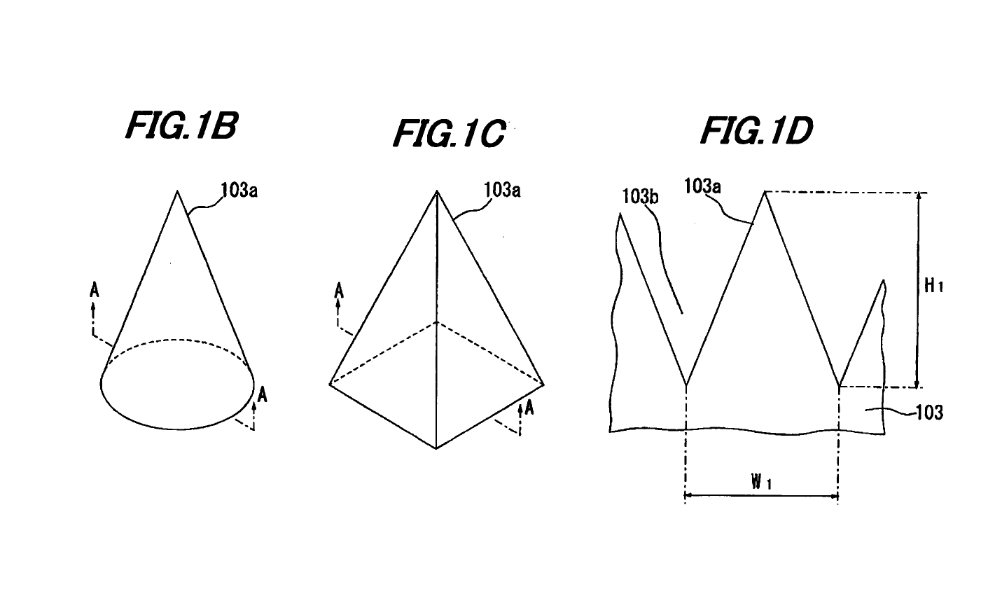

FIG. 1A is a schematic cross-sectional view showing a light emitting element in a first embodiment according to the invention. FIGS. 1B and 1C are schematic perspective views showing convex portions in the first embodiment according to the invention, and FIG. 1D is a cross-sectional view cut along the line A-A in FIGS. 1B and 1C.

Schematic Structure of Light Emitting Element 1

Referring to FIG. 1A, the light emitting element 1 according to the first embodiment includes a semiconductor stacked structure 10 including an active layer 105 for emitting a light having a predetermined wavelength, a surface electrode 110 electrically connected to a partial region of one surface of the semiconductor stacked structure 10, a contact part 120 brought into ohmic contact with a partial region of another surface of the semiconductor stacked structure 10, a transparent layer 140 disposed so as to contact the another surface of the semiconductor stacked structure 10 excluding a region where the contact part 120 is disposed, and a reflecting part 130 disposed on a surface of the contact part 120 and the transparent layer 140, the surface being located opposite to the surface of the contact part 120 and the transparent layer 140 which contacts the another surface of the semiconductor stacked structure 10.

Further, the light emitting element 1 includes an adhesion layer 200 having an electrical conductivity and disposed on a surface of the reflecting part 130, the surface being located opposite to the surface of the reflecting portion 130 which contacts the contact part 120 and the transparent layer 140, and a supporting substrate 20 disposed on a surface of the adhesion layer 200, the surface being located opposite to the surface of the adhesion layer 200 which contacts the reflecting part 130. And, the supporting substrate 20 has a rear surface electrode 210 disposed on a surface of the supporting substrate 20, the surface being located opposite to the surface of the supporting substrate 20 which contacts the adhesion layer 200, namely, disposed on a rear surface of the supporting substrate 20.

Further, the semiconductor stacked structure 10 of the light emitting element 1 according to the embodiment includes a p-type contact layer 109 disposed so as to contact the contact part 120 and the transparent layer 140, a p-type cladding layer 107 as a second semiconductor layer of second conductivity type disposed on a surface of the p-type contact layer 109, the surface being located opposite to the surface thereof which contacts the transparent layer 140, an active layer 105 disposed on a surface of the p-type cladding layer 107, the surface being located opposite to the surface thereof which contacts the p-type contact layer 109, a n-type cladding layer 103 as a first semiconductor layer of first conductivity type disposed on a surface of the active layer 105, the surface being located opposite to the surface thereof which contacts the p-type cladding layer 107, and a n-type contact layer 101 disposed on a partial region of the n-type cladding layer 103, the partial region being located opposite to the surface thereof which contacts the active layer 105.

The surface of the semiconductor stacked structure 10 being located opposite to the surface thereof which contacts the transparent layer 140 functions as a light extraction surface of the light emitting element 1 according to the embodiment. In particular, a partial surface of the n-type cladding layer 103, the partial surface being located opposite to the surface thereof which contacts the active layer 105, namely, a part excluding a region just under a surface electrode 110 functions as the light extraction surface. And, in the light extraction surface of the n-type cladding layer 103, plural convex portions 103a are formed as a plurality of convexities. A concave portion 103b is formed between one convex portion 103a and the other convex portion 103a adjacent to the one convex portion 103a. And, in each of the plural concave portions 103b, an embedded part 150 is formed, the embedded part 150 being made of a material capable of transmitting a light emitted from the active layer 105. The embedded part 150 can reduce stress which occurs in the convex portions 103a in comparison with a case that the embedded part 150 is not formed in the concave portion 103b.

Further, the reflecting part 130 includes a reflecting layer 132 disposed so as to contact the contact part 120 and the transparent layer 140, an alloying suppression layer 134 disposed so as to contact a surface of the reflecting layer 132, the surface being located opposite to the surface thereof which contacts the portion 120 and the transparent layer 140 and a joining layer 136 disposed so as to contact a surface of the alloying suppression layer 134, the surface being located opposite to the surface thereof which contacts the reflecting layer 132. And, the adhesion layer 200 includes a joining layer 202 electrically and mechanically connected to the joining layer 136 of the reflecting part 130, and a contact electrode 204 disposed on a surface of the joining layer 202, the surface being located opposite to the surface thereof which contacts the reflecting part 130. And, the rear surface electrode 210 is formed so as to include a rear surface contact electrode 212 brought into ohmic contact with the rear surface of the supporting substrate 20, and a die bonding electrode 214 disposed on a surface of the rear surface contact electrode 212, the surface being located opposite to the surface thereof which contacts the supporting substrate 20.

The light emitting element 1 according to the embodiment is formed almost in a square shape on the plan view. As an example, the light emitting element 1 has dimensions in a plan view that a longitudinal dimension is 250 μm and a lateral dimension is 250 μm. Further, the light emitting element 1 is formed so as to have a thickness of almost 200 μm. Furthermore, the light emitting element 1 according to the embodiment can be also formed, for example, so as to have a dimension in a plan view of not less than 500 μm, and as an example, so as to have a large-scaled chip size of 1 mm square.

Convex Portion 103a, Concave Portion 103b, and Embedded Part 150

The convex portion 103a according to the embodiment is formed so as to have a cross section structure that becomes gradually narrow in the direction directed from the active layer 105 to the surface electrode 110 (or the light extraction surface). In this case, if the plural convex portions 103a are formed, simultaneously, concave portions 103b are relatively formed. Also, if the plural concave portions 103b are formed so as to have a cross section structure that becomes gradually narrow in the direction directed from the light extraction surface to the active layer 105, simultaneously, the plural convex portions 103a are relatively formed.

In particular, each of the plural convex portions 103a having a cone shape shown in FIG. 1B, or a pyramid shape shown in FIG. 1C on a perspective view is formed on the surface the n-type cladding layer 103. In case that the convex portion 103a has a cone shape or a pyramid shape, a direction to which a vertex of the cone shape or a pyramid shape is directed becomes a direction to which a light finally outputted from the light emitting element 1 is directed, the light being originally emitted from the active layer 105.

Further, FIG. 1D is a transverse cross-sectional view of the convex portions 103a, particularly, is a transverse cross-sectional view taken along the line A-A in FIGS. 1B and 1C. The convex portion 103a according to the embodiment is formed so as to have a shape that a length W₁ of “horizontal portion” along a surface parallel to the active layer 105 is not more than a length H₁ of “height portion” in a direction perpendicular to the horizontal surface on a cross sectional view. Further, in case that the convex portion 103a has a three-sided pyramid shape, the cross section is defined as a surface that passes through a vertex of the three-sided pyramid shape, a vertex of triangular shape on the bottom face of the three-sided pyramid shape, and a midpoint of the bottom facing to the vertex of triangular shape. Namely, the convex portion 103a becomes to have a cross sectional shape of almost a triangular shape, and the convex portion 103a is formed to have a shape that a ratio of a height of the triangular shape to a base thereof becomes not less than 1. Therefore, the convex portion 103a according to the embodiment is formed in an acute-angled triangular shape. As an example, the convex portion 103a is formed so as to have an angle at the end of the cone shape or the pyramid shape of not more than 40 degrees.

The concave portions 103b are formed in regions surrounded by the plural convex portions 103a. And, an embedded part 150 is disposed in each of the concave portions 103b, the embedded part 150 being formed by embedding a material which transmits a light emitted from the active layer 105 in each of the concave portions 103b. The embedded part 150 is formed by embedding a material which can reduce stress occurring in the plural convex portions 103a in each of the concave portions 103b. Namely, the stress is reduced due to the fact that a difference between a linear expansion coefficient of a semiconductor material constituting the convex portion 103a and that of a material constituting the embedded part 150 is small.

In particular, the embedded part 150 is formed of a material having the linear expansion coefficient close to that of the semiconductor material constituting the convex portion 103a and the embedded part 150 is formed of a material which has a linear expansion coefficient of not more than 1×10⁻⁵/K. Further, the embedded part 150 can be also formed of a material having a refractive index less than that of the semiconductor material constituting the convex portion 103a.

For example, the embedded part 150 can be formed of an insulating transparent material such as silicon oxide (SiO₂), silicon nitride (Si₃N₄), magnesium fluoride (MgF₂), a transparent conductive material such as indium tin oxide (ITO), tin oxide (SnO₂), zinc oxide (ZnO), or a wide bandgap compound semiconductor material such as zinc sulfide (ZnS), zinc selenide (ZnSe). Further, in case that the embedded part 150 is formed of ITO, it is preferable to use an insulating ITO with high transparency obtained by being formed under a predetermined oxygen atmosphere so as to prevent an oxygen defection from ITO and control a dopant concentration. Further, in case that the embedded part 150 is formed of the wide bandgap compound semiconductor material, the semiconductor material can be formed of any one of single crystal and polycrystal, if it can transmit a light emitted from the active layer 105. Furthermore, in case that the embedded part 150 is formed of a conductive material such as ITO, an effect is provided that electrical current supplied to the light emitting element 1 is dispersed in the embedded part 150.

Semiconductor Stacked Structure 10

The semiconductor stacked structure 10 according to the embodiment is formed so as to have a AlGaInP-based compound semiconductor which is a III-V group compound semiconductor. For example, the semiconductor stacked structure 10 has a structure that the active layer 105 formed so as to have a quantum well structure of the AlGaInP-based compound semiconductor is sandwiched between the n-type cladding layer 103 formed so as to have a n-type AlGaInP and the p-type cladding layer 107 formed so as to have a p-type AlGaInP.

The active layer 105 emits a light having a predetermined wavelength, if electric current is externally supplied. For example, the active layer 105 is formed so as to have a quantum well structure emitting a red light having a wavelength of almost 630 nm. Further, as the quantum well structure, any of a single quantum well structure, a multiple quantum well structure and a strained quantum well structure can be adopted. Further, the n-type cladding layer 103 contains an n-type dopant such as Si, Se at a predetermined concentration. As an example, the n-type cladding layer 103 is formed of an n-type AlGaInP layer doped with Si. Further, the p-type cladding layer 107 contains a p-type dopant such as Zn, Mg at a predetermined concentration. As an example, the p-type cladding layer 107 is formed of a p-type AlGaInP layer doped with Mg.

Further, the p-type contact layer 109 constituting the semiconductor stacked structure 10 is formed of, as an example, a p-type GaP layer doped with high concentration of Mg. And, the n-type contact layer 101 is formed of, as an example, a n-type GaAs layer doped with high concentration of Si. Here, the n-type contact layer 101 is formed on a part of top surface of the n-type cladding layer 103 corresponding to a region where the surface electrode 110 is formed.

Contact Part 120

The contact part 120 is formed on a part of the surface of p-type contact layer 109. The contact part 120 is formed of a material brought into ohmic contact with the p-type contact layer 109, and as an example, is formed of a metal alloy material including Au and Be, or Au and Zn. The contact part 120 is formed so as to have a shape that on a plan view, electric current supplied from the surface electrode 110 can be supplied to almost the whole surface of the active layer 105, for example, a comb shape. Further, the contact part 120 according to the embodiment is formed also on a part just under the surface electrode 110, but in a modification example of the embodiment, the contact part 120 can be also formed on a region excluding the part just under the surface electrode 110.

Transparent Layer 140

The transparent layer 140 is formed on a part of surface of the reflecting part 130 (or the surface of the p-type contact layer 109) corresponding to a region where the contact part 120 is not formed. The transparent layer 140 is formed of a material which transmits a light emitted from the active layer 105, and as an example, is formed of a transparent dielectric layer such as SnO₂, TiO₂, SiNx. The transparent layer 140 has a function as an electric current inhibition layer that electric current is not transmitted in a part where the transparent layer 140 is disposed. The electric current supplied to the light emitting element 1 is not transmitted through the transparent layer 140 as the electric current inhibition layer, but is transmitted through the semiconductor stacked structure 10 and the supporting substrate 20 via the contact part 120.

Reflecting Part 130

The reflecting layer 132 of the reflecting part 130 is formed of a conductive material having a high reflectivity to a light emitted from the active layer 105. As an example, the reflecting layer 132 is formed of a conductive material having a reflectivity of not less than 80% to the light. The reflecting layer 132 reflects a light reached the reflecting layer 132 of the light emitted from the active layer 105 so as to be directed for the side of active layer 105. The reflecting layer 132 is formed of, for example, a metal material such as Al, Au, Ag or an alloy containing at least one selected from the metal material. As an example, the reflecting layer 132 is formed of a Au film having a predetermined thickness. Further, the reflecting layer 132 is electrically connected to the contact part 120.

The alloying suppression layer 134 of the reflective part 130 is formed of a metal material such as Ti, Pt, and as an example, is formed of a Ti film having a predetermined thickness. The alloying suppression layer 134 prevents a material constituting the joining layer 136 from diffusing to the reflecting layer 132. Further, the joining layer 136 is formed of a material electrically and mechanically joined to the joining layer 202 of the adhesion layer 200, as an example, is formed of a Au film having a predetermined thickness.

Supporting Substrate 20

The supporting substrate 20 is formed of a conductive material. For example, the supporting substrate 20 can be formed of a semiconductor substrate such as a p-type or n-type conductive Si substrate, Ge substrate, GaAs substrate, GaP substrate or a metal substrate formed of a metal material such as Cu. As an example, in the embodiment, as the supporting substrate 20, a conductive Si substrate having a low resistance can be used.

And, the joining layer 202 of the adhesion layer 200, as well as the joining layer 136 of the reflective part 130, can be formed of a Au film having a predetermined thickness. Further, the contact electrode 204 is formed of a metal material such as Ti brought into ohmic contact with the supporting substrate 20. And, the rear surface electrode 210 disposed on a rear surface of the supporting substrate 20 includes the rear surface contact electrode 212 formed of a metal material such as Al, Ti brought into ohmic contact with the supporting substrate 20 and the die bonding electrode 214 disposed on a surface of the rear surface contact electrode 212 opposite to the supporting substrate 20 and formed of a metal material such as Au.

Further, the light emitting element 1 is mounted at a predetermined position of a stem formed of a metal such as Cu by using a conductive joining material such as a Ag paste or an eutectic material such as AuSn, in a state that the rear surface of the supporting substrate 20 (namely, the exposed surface of the rear surface electrode 210) is directed downward. The light emitting element 1 mounted on a predetermined region of the stem can be provided as a light emitting device by that the surface electrode 110 and the predetermined region of the stem are connected by a wire made of Au or the like and simultaneously, the whole of the light emitting element 1 and the wire are covered with a transparent resin such as epoxy resin, silicon resin.

Modification

The light emitting element 1 according to the embodiment emits a red light having a wavelength of almost 630 nm, the wavelength emitted from the light emitting element 1 is not limited to the above-mentioned wavelength. A structure of the active layer 105 of the semiconductor stacked structure 10 can be controlled so as to form the light emitting element 1 emitting a light having a predetermined wavelength range. The light emitted from the active layer 105 includes a light having a wavelength range of such as an orange light, a yellow light, a green light. Further, the semiconductor stacked structure 10 constituting the light emitting element 1 can be formed of a GaN compound semiconductor including the active layer 105 emitting a light of an ultraviolet region, a violet region or a blue region.

The convex portion 103a according to the embodiment is formed so as to have a cone shape or a pyramid shape, but in the modification of the embodiment, the convex portion 103a is not limited to being formed in the cone shape or the pyramid shape, if each surface constituting the convex portion 103a is formed of a surface that intersects at an acute angle to a horizontal surface parallel to the active layer 105. Further, the convex portion 103a of the modification can be formed so as to have a convex shape that the end portion is sharpened and the cross section has an aspect ratio. As an example, the convex portion 103a according to the modification of the embodiment can be formed in a three-sided pyramid shape. Further, the end portion of the convex portion 103a is not needed to have a steeple shape, and can be formed so as to have a somewhat round part or a microscopic flat surface (a microscopic surface parallel to the active layer 105).

In the embodiment, the embedded part 150 is formed so as to have a flat surface, but can be also formed so as to have some concavities and convexities in the surface, if the stress occurring in the convex portion 103a can be reduced. Further, the embedded part 150 can be formed so as to have a flat surface and simultaneously, to have air bubbles formed in the bottom of the embedded part 150 (the bottom of the concave portions 103b), namely, in the side of the n-type cladding layer 103 of embedded part 150. In this case, due to the existence of the air bubbles, the stress occurring in the convex portion 103a can be further reduced.

Further, in the embodiment, the end portion of the convex portion 103a and the surface of the embedded part 150 are formed so as to be almost in the same plane, but the surface of the embedded part 150 can be located lower than the end portion of the convex portion 103a, namely, closer to the side of the active layer 105. In this case, although the end portion of the convex portion 103a does not contact the surface of the embedded part 150, the vicinity of the end portion of the convex portion 103a is surrounded by the embedded part 150 so that the stress occurring in the convex portion 103a can be reduced.

Further, the embedded part 150 can include phosphor dispersed in a material transmitting the light emitted from the active layer 105, the phosphor being capable of emitting a wavelength conversion light different from the wavelength of the light emitted from the active layer 105 if it is excited by the light emitted from the active layer 105. For example, in case that the light emitted from the active layer 105 is a light of a blue region, a YAG phosphor can be dispersed in the embedded part 150, the YAG phosphor emitting a yellow light if excited by the blue light.

Further, the semiconductor stacked structure 10 composing the light emitting element 1 can have compound semiconductor layers with an opposite conductivity type to those in the first embodiment. For example, the n-type contact layer 101 and the n-type cladding layer 103 may be changed into p-type conductivity, and the p-type cladding layer 107 and the p-type contact layer 109 may be changed into n-type conductivity. Further, a wire-bonding pad may be formed on the top surface of the surface electrode 110. For example, when the surface electrode 110 is composed of a circular part and a thin wire electrode, the wire-bonding pad can be formed directly on the circular part.

The semiconductor stacked structure 10 may further have an n-side current spreading layer with a resistivity lower than the n-type cladding layer 103 between the n-type contact layer 101 and the n-type cladding layer 103. Further, the semiconductor stacked structure 10 may further have a p-side current spreading layer with a resistivity lower than the p-type cladding layer 107 between the p-type contact layer 109 and the p-type cladding layer 107. The semiconductor stacked structure 10 may have one or both of the n-side current spreading layer and the p-side current spreading layer. Due to the n-side current spreading layer and/or the p-side current spreading layer, current fed to the surface electrode 110 can spread in the surface direction of the light emitting element 1 to enhance the emission efficiency of the light emitting element 1. Further, due to the n-side current spreading layer and/or the p-side current spreading layer, the drive voltage can be reduced. The active layer 105 may have a bulk structure. For example, the active layer 105 can be formed of an undoped AlGaInP based compound semiconductor.

Fabrication Method of the Light Emitting Element 1

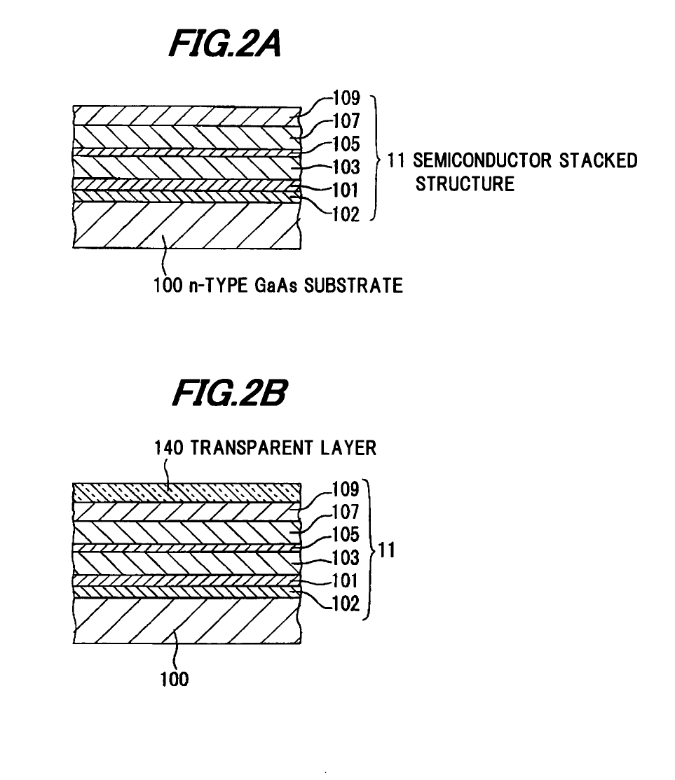

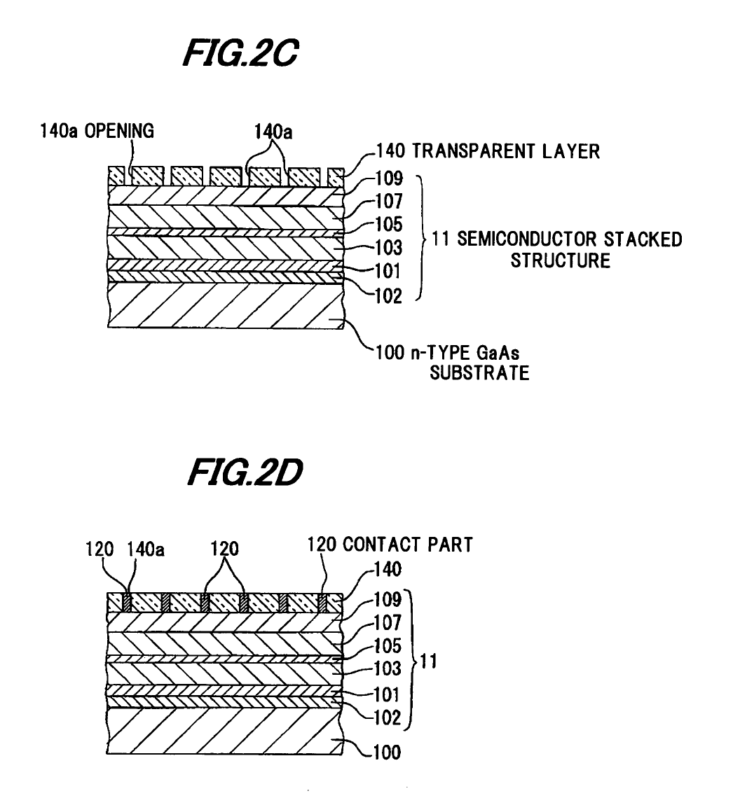

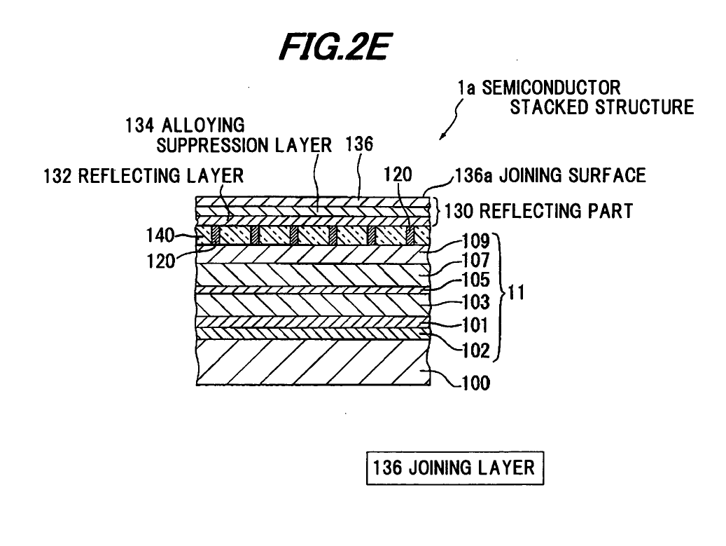

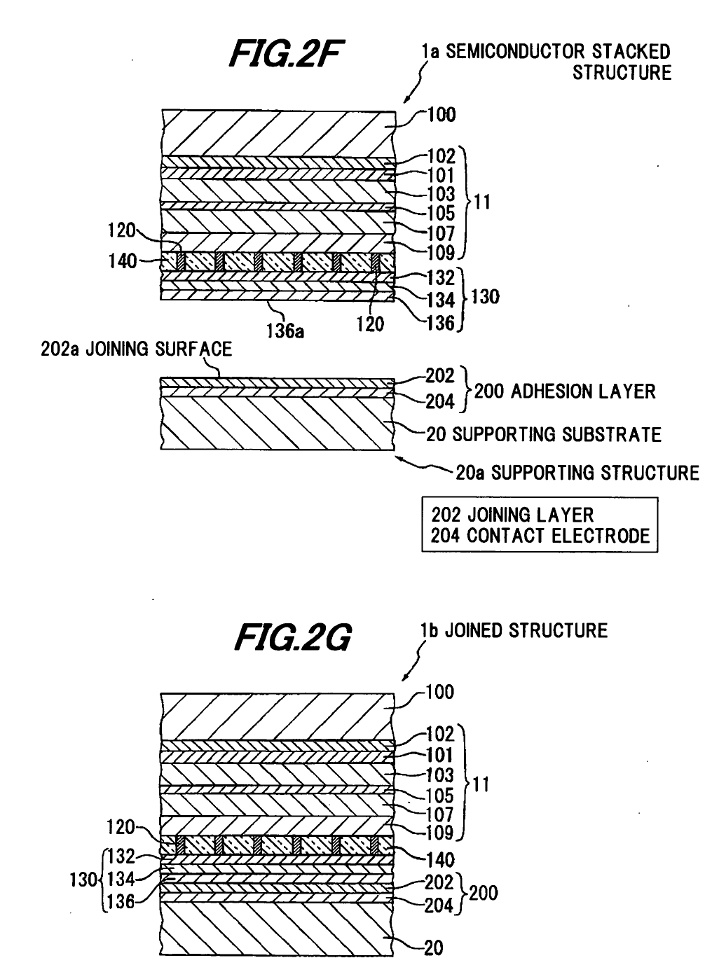

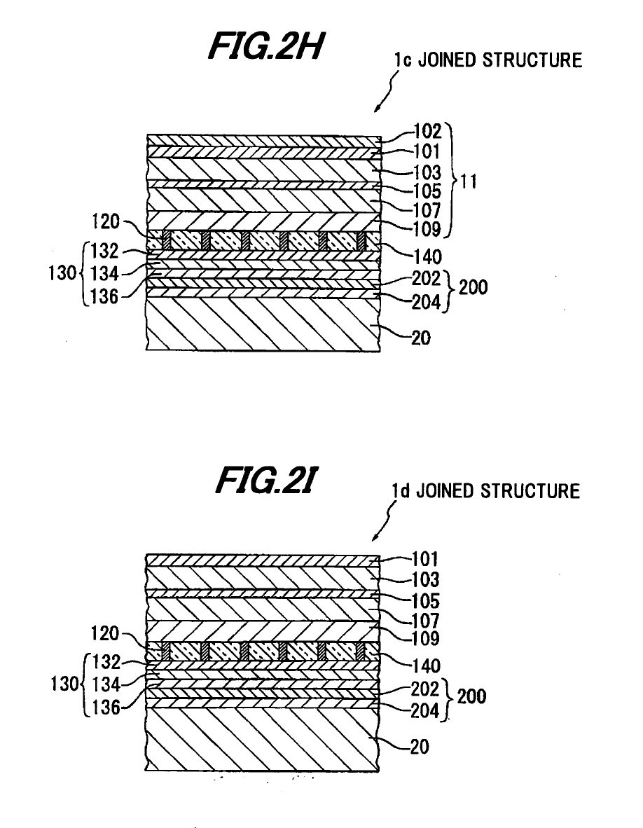

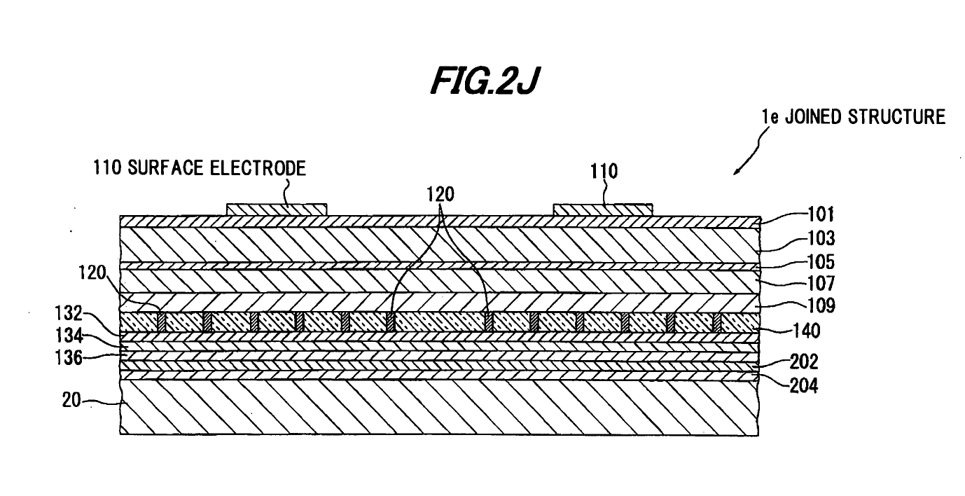

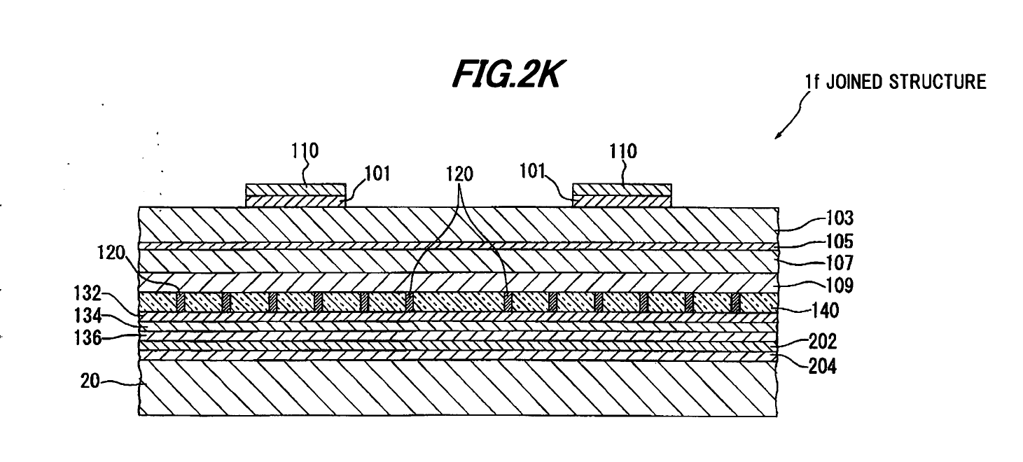

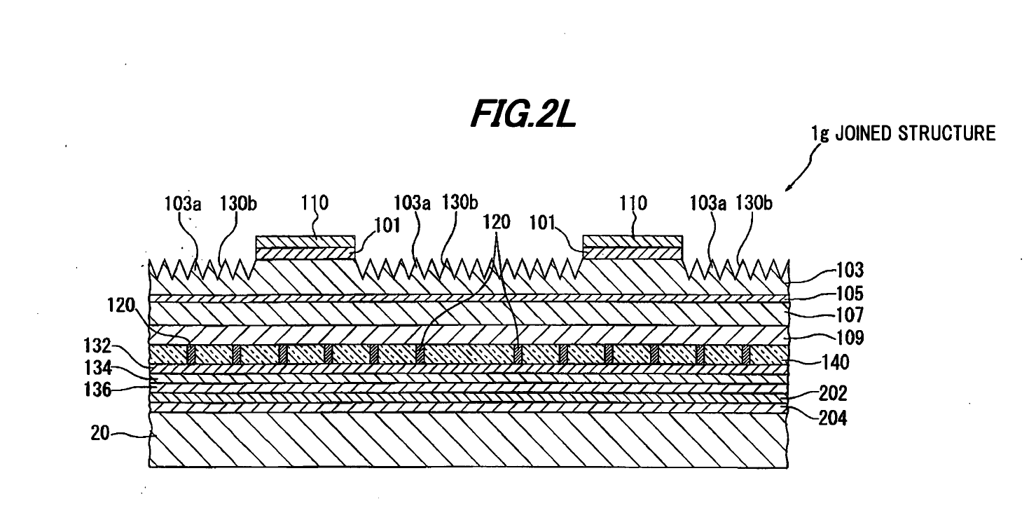

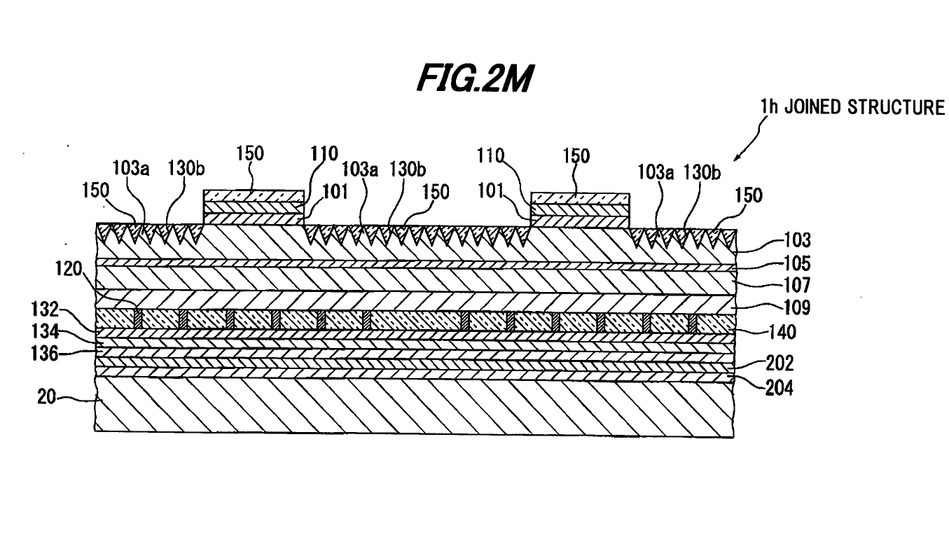

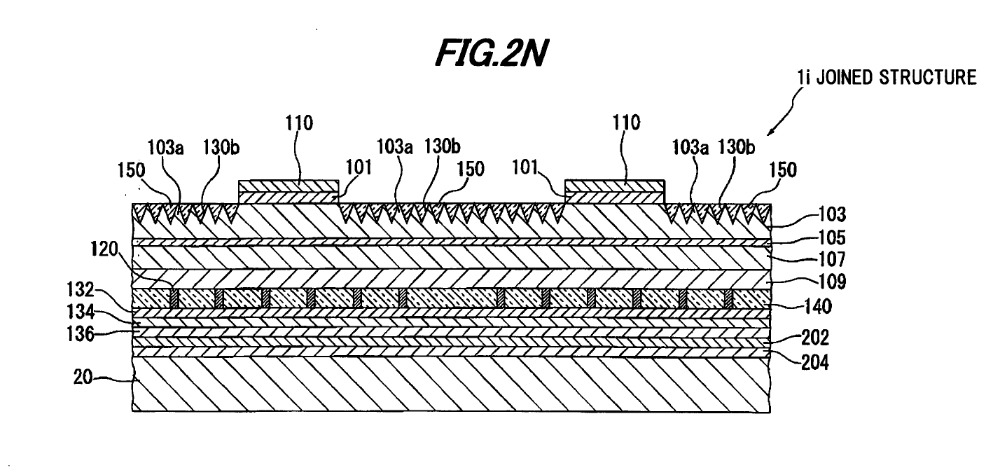

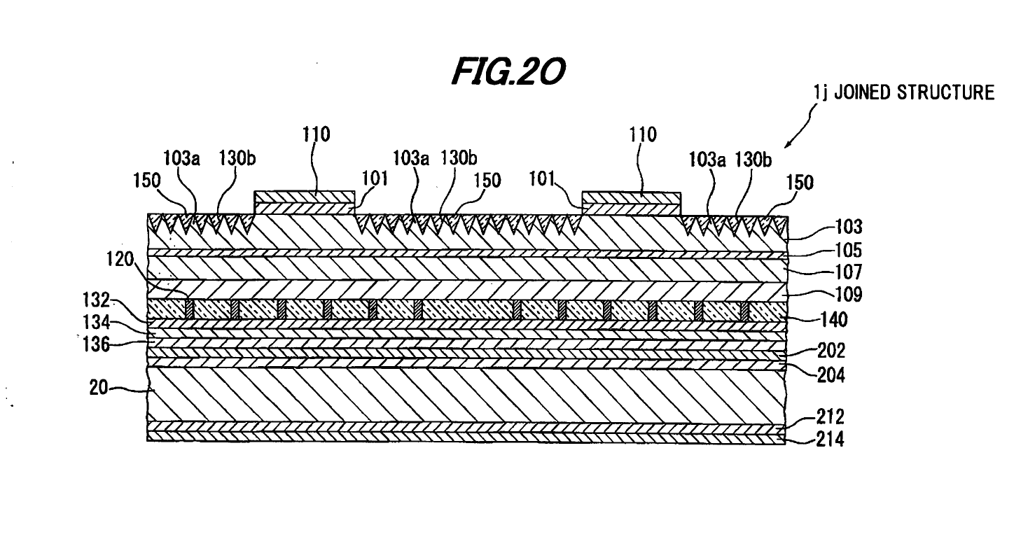

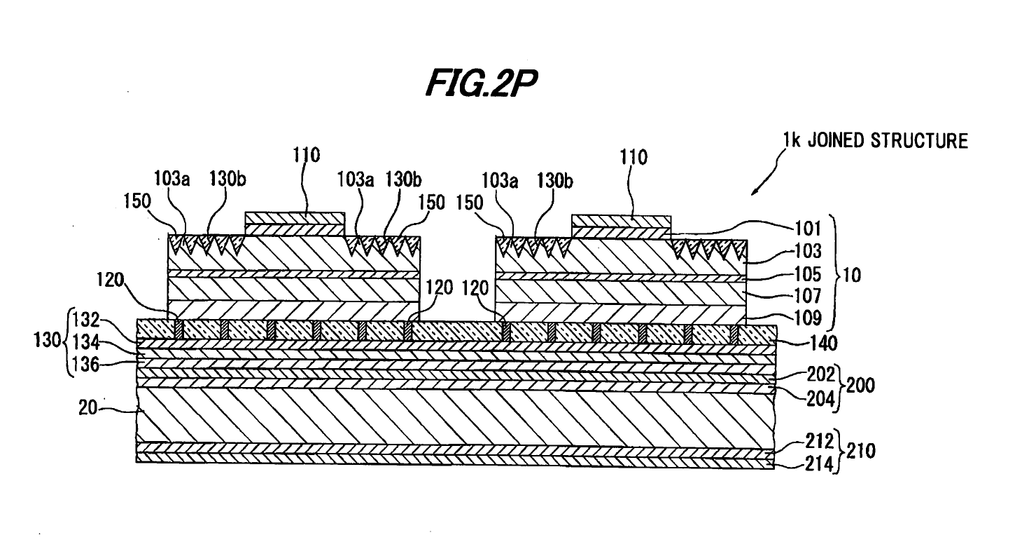

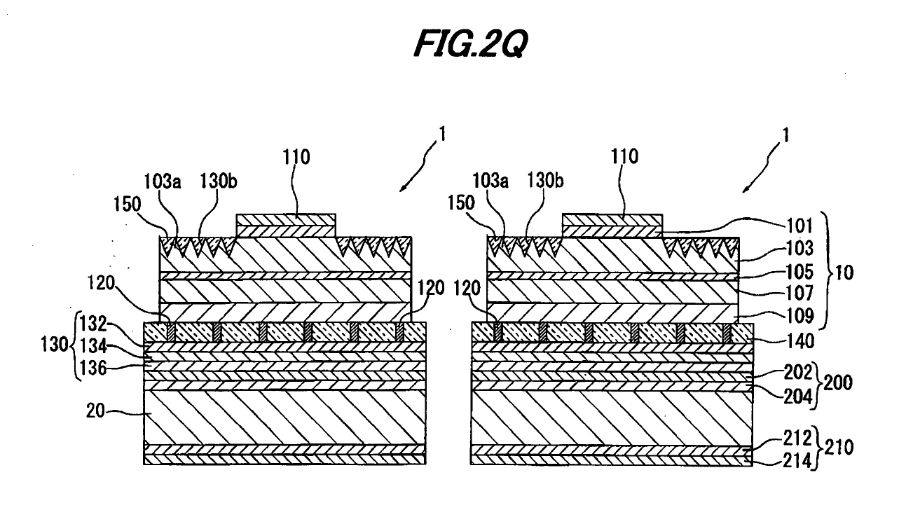

FIG. 2A to 2Q show a fabrication process flow for the light emitting element in the first embodiment of the invention.

First, as shown in FIG. 2A, an AlGaInP based semiconductor stacked structure 11 including plural compound semiconductor layers is formed on an n-type GaAs substrate 100 by, e.g., MOCVD (metal organic chemical vapor deposition). In this embodiment, the semiconductor stacked structure 11 is composed, formed on the n-type GaAs substrate 100, an etching stop layer 102, the n-type cladding layer 103, the active layer 105 and the p-type cladding layer 107.

For example, on the n-type GaAs substrate 100, the etching stop layer 102 of GaInP, the n-type contact layer 101 of n-type GaAs, the n-type cladding layer 103 of n-type AlGaInP, the quantum well type active layer 105 of AlGaInP, the p-type cladding layer 107 of p-type AlGaInP, and the p-type contact layer 109 of p-type GaP are formed in this order by MOCVD. Thereby, an epitaxial wafer is formed in which the semiconductor stacked structure 11 is formed on the n-type GaAs substrate 100. As described later, by forming the n-type contact layer 101 and the p-type contact layer 109, good electrical contact can be easy provided between the surface electrode 110 and the n-type contact layer 101 and between the p-type contact layer 109 and the contact part 120, respectively.

The raw material used for MOCVD can be organic metal compounds such as trimethylgallium (TMGa), trimethylgallium (TEGa), trimethylaluminum (TMAl), trimethylindium (TMIn) etc., and hydrides such as arsine (AsH₃), phosphine (PH₃) etc. The raw material for the n-type dopant can be disilane (Si₂H₆). The raw material for the p-type dopant can be biscyclopentadienyl magnesium (Cp₂Mg).

The raw material for the n-type dopant may be hydrogen selenide (H₂Se), monosilane (SiH₄), diethyltellurium (DETe) or dimethyltellurium (DMTe). The raw material for the p-type dopant may be dimethylzinc (DMZn) or diethylzinc (DEZn).

The semiconductor stacked structure 11 on the n-type GaAs substrate 100 may be formed by MBE (molecular beam epitaxy), HVPE (halide vapor phase epitaxy) etc.

Then, as shown in FIG. 2B, the epitaxial wafer in FIG. 2A is taken out of the MOCVD apparatus, and the transparent layer 140 is then formed on the p-type contact layer 109. For example, SiO₂ film as the transparent layer 140 is formed on the p-type contact layer 109 by using a plasma CVD (chemical vapor deposition) apparatus. The transparent layer 140 may be formed by the vacuum deposition.

Then, as shown in FIG. 2C, openings 140a are formed in the transparent layer 140 by using the photolithography and etching techniques. For example, a photoresist pattern with grooves at regions for forming the openings 140a is formed on the transparent layer 140. The opening 140a is formed extending from the surface of the transparent layer 140 to the interface between the p-type contact layer 109 and the transparent layer 140. For example, the opening 140a is formed in the transparent layer 140 by removing the transparent layer 140 at regions without the photoresist pattern by using a hydrofluoric etchant diluted with pure water. The opening 140a is formed at regions for forming the contact parts 120.

Then, as shown in FIG. 2D, AuBe alloy as a material for forming the contact part 120 is formed in the opening 140a by the vacuum deposition and liftoff techniques. For example, AuBe is vacuum deposited in the opening 140a by using as a mask the photoresist pattern used for forming the opening 140a so as to form the contact part 120.

Then, as shown in FIG. 2E, an Au layer as the reflecting layer 132, a Ti layer as the alloying suppression layer 134, and an Au layer as the joining layer 136 are formed on the transparent layer 140 and the contact part 120 by using the vacuum deposition and sputtering. Thereby, a semiconductor stacked structure 1a is formed. The alloying suppression layer 134 can be formed by stacking a high melting point material layer such as a Ti layer and a Pt layer insofar as it can suppress the material of the joining layer 136 from diffusing into the reflecting layer 132. Between the transparent layer 140 and the reflecting layer 132, an adhesion thin film may be further formed for enhancing the adhesion of the reflecting layer 132 to the transparent layer 140. The adhesion thin film can have a thickness substantially not absorbing light emitted from the active layer 105. The reflecting layer 132 can be formed of a high-reflectivity material selected according to the wavelength of light emitted from the active layer 105.

Then, as shown in FIG. 2F, Ti as the contact electrode 204 and Au as the joining layer 202 are in this order formed on the Si substrate as the supporting substrate 20 by vacuum deposition. Thereby, the supporting structure 20a is formed. Then, the joining surface 136a as the surface of the joining layer 136 of the semiconductor stacked structure 1a is stacked on the joining surface 202a of the joining layer 202 of the supporting structure 20a, and the stacking state is retained by using a fixture formed of a carbon etc.

Then, the fixture for retaining the stacking state of the semiconductor stacked structure 1a and the supporting structure 20a is carried into a wafer lamination apparatus (e.g., a wafer lamination apparatus for micromachines). The internal pressure of the wafer lamination apparatus is reduced to a predetermined pressure. Then, substantially uniform pressure is applied to the stacked semiconductor stacked structure 1a and the supporting structure 20a via the fixture. Then, the fixture is heated to a predetermined temperature at a temperature rise speed.

For example, the fixture is heated to 350° C. After the temperature of the fixture reaches about 350° C., the fixture is kept at the temperature for about one hour. Then, the fixture is cooled down. For example, the fixture is sufficiently cooled to a room temperature. After the temperature of the fixture lowers, pressure applied to the fixture is released. Then, the internal pressure of the wafer lamination apparatus is back to atmospheric pressure and the fixture is taken out of the apparatus. Thereby, as shown in FIG. 2G, a joined structure 1b is formed in which the semiconductor stacked structure 1a and the supporting structure 20a are mechanically joined between the joining layer 136 and the joining layer 202.

In this embodiment, the semiconductor stacked structure 1a has the alloying suppression layer 134. Therefore, even when the semiconductor stacked structure 1a and the supporting structure 20a are joined via the joining surface 136a and the joining surface 202a, the material composing the joining layer 136 and the joining layer 202 can be suppressed from diffusing into the reflecting layer 132 to prevent the deterioration of the reflection performance of the reflecting layer 132.

Then, the joined structure 1b is attached to a fixture of a polishing apparatus by using an attaching wax. For example, the supporting substrate 20 side is attached to the fixture. Then, the n-type GaAs substrate 100 of the joined structure 1b is polished to a predetermined thickness. For example, the n-type GaAs substrate 100 is polished until the remaining thickness of the n-type GaAs substrate 100 becomes about 30 μm. Then, the polished joined structure 1b is released from the fixture of the polishing apparatus and the wax on the surface of the supporting substrate 20 is removed by washing. Then, as shown in FIG. 2H, the n-type GaAs substrate 100 is selectively and perfectly removed from the polished joined structure 1b by using the etchant for etching GaAs so as to form a joined structure 1c with the etching stop layer 102 exposed thereon. For example, the GaAs etching etchant can be a mixed solution of ammonia water and hydrogen peroxide water. Alternatively, the n-type GaAs substrate 100 may be all removed by etching without polishing.

Then, as shown in FIG. 2I, the etching stop layer 102 is removed from the joined structure 1c by etching by using a predetermined etchant. Thereby, a joined structure 1d without the etching stop layer 102 can be formed. When the etching stop layer 102 is formed of GaInP, the etchant can be an etchant including hydrochloric acid. Thereby, the surface of the n-type contact layer 101 is exposed.

Then, the surface electrode 110 is formed at a predetermined position on the n-type contact layer 101 by using the photolithography and vacuum deposition techniques. For example, as shown in FIG. 2J, the surface electrodes 110 are formed on the n-type contact layer 101. The surface electrode 110 is composed of a circular part with a diameter of 100 μm, and plural thin wire electrodes extending from the circular part to the outside of the circular part. The surface electrode 110 is formed by depositing AuGe, Ni and Au in this order on the n-type contact layer 101. Thereby, as shown in FIG. 2J, a joined structure 1e with the surface electrodes 110 can be formed.

Then, as shown in FIG. 2K, by using the surface electrode 110 in FIG. 2J as a mask, the n-type contact layer 101 except a part directly under the surface electrode 110 is removed by etching with a mixed solution of sulfuric acid, hydrogen peroxide water and water. Thereby, a joined structure 1f can be formed. By suing the mixed solution, the n-type contact layer 101 of GaAs can be etched selectively relative to the n-type cladding layer 103 of n-type AlGaInP. Thereby, in the joined structure 1f, the surface of the n-type cladding layer 103 is exposed.

Then, as shown in FIG. 2L, plural convex portions 103a are formed at a part of the surface of the n-type cladding layer 103. The plural convex portions 103a are formed conical or pyramidal as shown in FIGS. 1B and 1C. For example, a mask pattern with patterns repeated at predetermined intervals for the convex portion 103a and the concave portion 103b is formed on the surface of the n-type cladding layer 103 by using the photolithography. The formed patterns are arranged in the form of a matrix, honeycomb etc. Using the mask pattern as a mask, the convex portions 103a and the concave portions 103b are formed on the surface of the n-type cladding layer 103 by dry etching. Then, the mask is removed to form a joined structure 1g with the convex portions 103a and the concave portions 103b.

Then, an SiO₂ layer with the same height as the convex portion 103a is formed by CVD such that the concave portions 103b are filled with SiO₂. Thereby, as shown in FIG. 2M, a joined structure 1h is formed such that the concave portions 103b are each filled with SiO₂ and the SiO₂ layer is formed on the surface electrode 110. The SiO₂ layer may be formed by the solution or coating technique. When the SiO₂ layer is formed by the solution or coating technique, the surface of the SiO₂ layer can be easy flattened and the uppermost surface of the embedded part 150 detailed later can be also easy flattened. When the concave portion 103b is embedded with a semiconductor material, the semiconductor layer may be epitaxially grown therein in place of the SiO₂ layer. The epitaxially grown semiconductor layer is excellent in crystalline quality so that transparency to light emitted from the active layer 105 can be enhanced.

Then, a mask is formed which has openings at regions corresponding to the surface electrode 110. Then, the SiO₂ layer on the surface electrode 110 is removed which is exposed through the opening of the mask. Then, the mask is removed. Thereby, as shown in FIG. 2N, a joined structure 1h is formed in which the plural concave portions 103b are embedded with SiO₂. Then, on almost the entire back face of the supporting substrate 20, the rear surface contact electrode 212 of Al and the die bonding electrode 214 of Au are formed by vacuum deposition. Thereby, as shown in FIG. 2O, a joined structure 1j is formed which has the rear surface contact electrode 212 and the die bonding electrode 214. Then, the joined structure 1j is subjected to an alloying process whereby electrical junctions are formed between the contact part 120 and the p-type contact layer 109 and between the surface electrode 110 and the n-type contact layer 101, respectively. For example, the joined structure 1j is subjected to the alloying process at about 400° C. in a nitrogen inert atmosphere.

Then, a mask pattern for separation between light emitting elements is formed on the surface of the joined structure 1j by photolithography. For example, the mask pattern for light emitting element separation is formed on the surface of the n-type cladding layer 103 of the joined structure 1j. Then, by using the mask pattern as a mask, a section region from the surface side of the n-type cladding layer 103 to the p-type contact layer 109 is removed by wet etching such that the light emitting elements are separated each other. Thereby, as shown in FIG. 2P, a joined structure 1k is formed which has plural separated light emitting elements.

Then, by using dicing equipment with a dicing blade, the joined structure 1k is diced into chips. Thereby, as shown in FIG. 2Q, the plural light emitting elements 1 of this embodiment are obtained. As explained above, the semiconductor layers of the joined structure 1k including the active layer 105 are separated by wet etching, so that the semiconductor layers including the active layer 105 can be prevented from having mechanical defects that may be caused upon the element separation by using the dicing equipment.

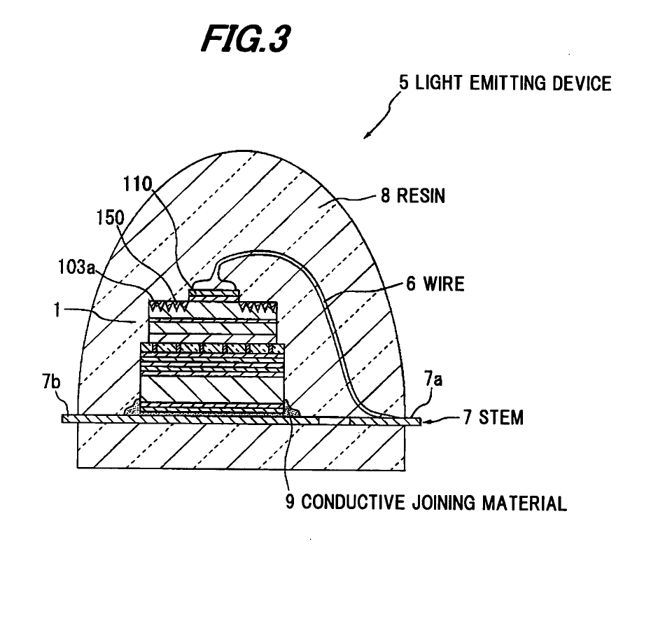

FIG. 3 is a schematic cross-sectional view showing a light emitting device mounting a light emitting element in the first embodiment according to the invention.

The light emitting element 1 is mounted on a stem 7 formed of a metallic material such as Cu, Al etc. For example, the light emitting element 1 is mounted on an element mounting region 7b of the stem 7 via a conductive joining material 9 for joining mechanically the light emitting element 1 to the stem 7. For example, the conductive joining material 9 can be a conductive adhesive such as Ag paste or an eutectic material such as AuSn. Then, the surface electrode 110 is bonded to a current feeding part 7a of the stem 7 by a wire 6 of Au etc. Then, the light emitting element 1 and the wire 6 are sealed with a transparent resin 8 such as epoxy resin, silicone etc. Thereby, a light emitting device 5 can be obtained.

In this embodiment, the embedded part 150 embedded in the concave portion 103b is formed of a material that has a linear expansion coefficient smaller than the resin 8 and close to that of the semiconductor material composing the convex portion 103a. In other words, the embedded part 150 is formed of such a material that the difference between the linear expansion coefficient of the semiconductor material composing the convex portion 103a and that of the material composing the embedded part 150 is smaller than the difference between the linear expansion coefficient of the material composing the embedded part 150 and that of the resin 8.

For example, AlGaInP semiconductor composing the n-type cladding layer 103 has a linear expansion coefficient of about 4×10⁻⁶ to 8×10⁻⁶/K. On the other hand, silicone used for the resin 8 has a linear expansion coefficient of about 100×10⁻⁶ to 500×10⁻⁶/K. The embedded part 150 of the embodiment is formed of a material with a linear expansion coefficient of not more than 10×10⁻⁶/K. Thus, the convex portion 103a can be suppressed from being subjected to stress caused by temperature change.

The embedded part 150 may be composed of a material with a refractive index greater than the resin 8. In this case, the refractive index lowers in the order of the semiconductor material composing the convex portion 103a, the material composing the embedded part 150, and the material composing the resin 8. Thus, the embedded part 150 is formed of the material with a refractive index between that of the material composing the convex portion 103a and that of the material composing the resin 8 for sealing the light emitting element 1.

### Effects of the First Embodiment

The light emitting element 1 of the first embodiment is constructed such that the concave portion 103b formed on the light extraction side is embedded with the material with a linear expansion coefficient close to that of the semiconductor material composing the convex portion 103a. Therefore, even when thermal shock is applied to the light emitting device 5 produced by sealing the light emitting element 1 with the resin 8, stress occurred in the convex portion 103a can be reduced. Thereby, the convex portion 103a is suppressed from being cracked or broken such that the light emitting element 1 and the light emitting device 5 can be enhanced in reliability.

The light emitting element 1 of the first embodiment is constructed such that the concave portion 103b is embedded with the material with a linear expansion coefficient close to that of the material composing the convex portion 103a. Therefore, even when thermal shock is applied to the light emitting device 5, stress occurred in the convex portion 103a can be reduced. If the concave portion 103b is embedded with silicone, the convex portion 103a may be subjected to stress as large as 10⁶ to 10⁹ Pa so that the convex portion 103a with a sharp tip may be broken. In this embodiment, such a breakage can be significantly suppressed.

Further, the light emitting element 1 of the first embodiment is constructed such that the refractive-index difference between the embedded part 150 and the resin 8 is smaller than that between the n-type cladding layer 103 and the resin 8. Therefore, the light extraction angle at the light extraction surface increases. Thereby, the light emitting device 5 using the light emitting element 1 in the embodiment can have significantly improved light extraction efficiency.

When the embedded part 150 is formed of an inorganic material such as SiO₂, the surface of the n-type cladding layer 103 can be suppressed from deteriorating due to moisture or oxygen which may externally penetrate into the resin 8 composing the light emitting device 5. Thus, the light emitting element 1 and the light emitting device 5 can be enhanced in moisture resistance and oxygen resistance.

### Modification of the First Embodiment

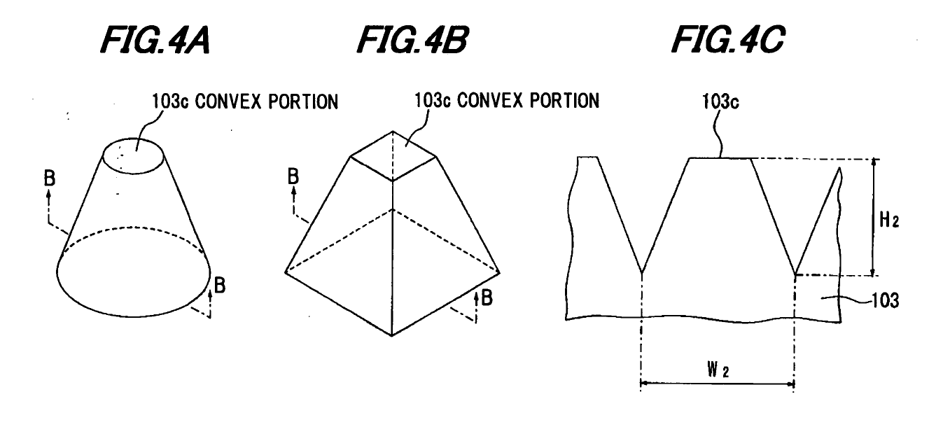

FIGS. 4A to 4C show convex portions in a modification of the first embodiment of the invention.

A light emitting element of the modification has the same composition as the light emitting element 1 of the first embodiment except that the shape of the convex portion is different. Thus, the detailed explanation of the components except the different components will be omitted below.

Referring to FIG. 4A (perspective view), a convex portion 103c may be shaped like a truncated cone. Referring to FIG. 4B (perspective view), a convex portion 103c may be shaped like a truncated pyramid. FIG. 4C is a cross sectional view of the convex portion 103c, i.e., a cross sectional view cut along the line B-B in FIGS. 4A and 4B.

The convex portion 103c is formed such that, in the cross section, a width W₂ of a bottom portion thereof along a parallel plane to the active layer 105 is not more than a height H₂ thereof perpendicular to the parallel plane. In other words, the convex portion 103c is shaped like a trapezoid in the cross section, and the convex portion 103c is formed such that the ratio of the height to the base in the trapezoid is not less than 1. Thus, the cross section of the convex portion 103c is formed trapezoidal so that the breakage of the convex portion 103c can be significantly suppressed.

### Second Embodiment

FIG. 5 is a schematic cross-sectional view showing a part of a light emitting element in a second preferred embodiment according to the invention.

The light emitting element 2 of the second embodiment has the same composition as the light emitting element 1 of the first embodiment except that the thickness of the embedded part 150 is different. Thus, the detailed explanation of the components except the different components will be omitted below.

The light emitting element 2 of the second embodiment is constructed such that the embedded part 150 is formed to cover the tip portion of the convex portion 103a as well as the inside of the concave portion 103b. Namely, the embedded part 150 of the second embodiment is formed to have a thickness greater than that of the first embodiment. The light emitting element 2 of the second embodiment can also reduce stress occurred in the convex portion 103a since the convex portion 103a is completely enclosed by the embedded part 150.

### Third Embodiment

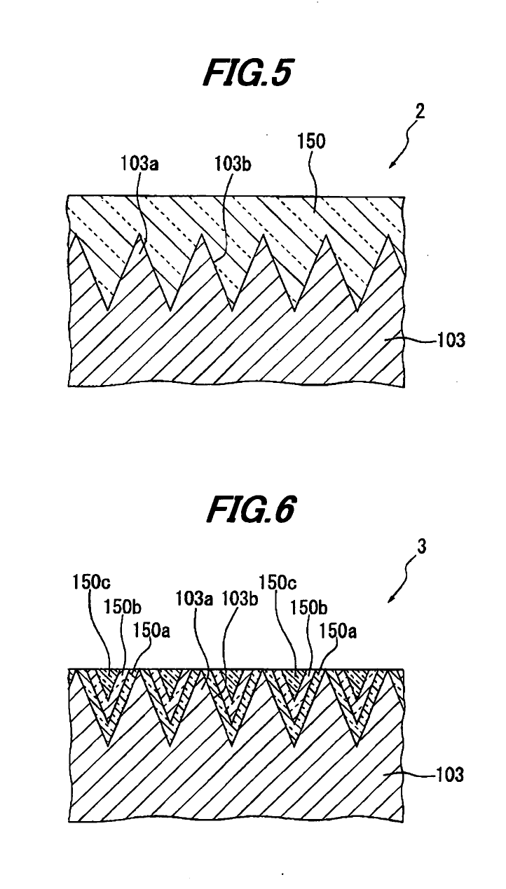

FIG. 6 is a schematic cross-sectional view showing a part of a light emitting element in a third preferred embodiment according to the invention.

The light emitting element 3 of the third embodiment has the same composition as the light emitting element 1 of the first embodiment except that the structure of the embedded part 150 is different. Thus, the detailed explanation of the components except the different components will be omitted below.

The light emitting element 3 of the third embodiment is provided with the embedded part 150 composed of multiple embedded layers stacked. For example, a first embedded layer 150a is formed on the concave portion 103b, a second embedded layer 150a is formed on the first embedded layer 150a, and a third embedded layer 150c is formed on the first embedded layer 150b. Thus, the embedded part 150 of the third embodiment is composed of the first to third embedded layers 150a to 150c.

The materials for forming the first to third embedded layers 150a to 150c composing the embedded part 150 may be different from each other. The material of the embedded part 150 can be a semiconductor material with a high refractive index (e.g., with a refractive index of about 2 to 3) or a semiconductor material with a low refractive index (e.g., with a refractive index of about 1.3 to 1.5). For example, it can be MgF₂ (1.38 in refractive index), SiO₂ (1.45 in refractive index), ZnS (2.37 in refractive index), Si₃N₄ (2 in refractive index) etc. An example is made such that the refractive index lowers in the order of the first embedded layer 150a, the second embedded layer 150b and the third embedded layer 150c. Where the refractive index lowers gradually from the first embedded layer 150a to the third embedded layer 150c, the refractive index difference from that of the external air can be reduced gradually so that the reflectively (of light extracted through the embedded part 150) at the light extraction surface can be reduced.

According to the light emitting element 3 of the third embodiment, the embedded part 150 is in multilayer structure so that the light extraction efficiency and the reliability can be significantly enhanced.

Modification of the Third Embodiment

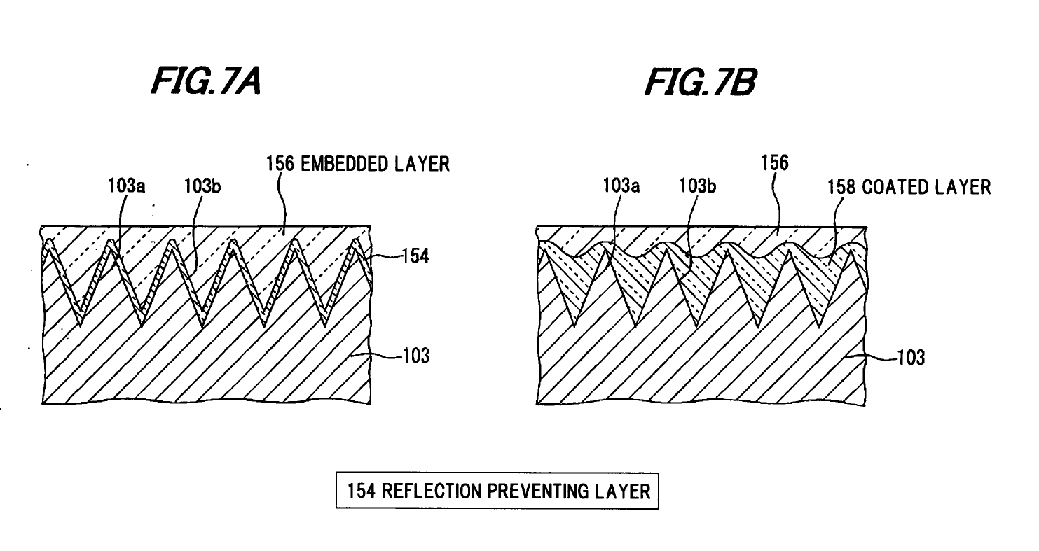

FIGS. 7A and 7B are each schematic cross-sectional views showing a part of light emitting elements in modification of the third embodiment according to the invention.

The light emitting elements in modification of the third embodiment have the same composition as the light emitting element 1 of the first embodiment except that the structure of the embedded part 150 is different. Thus, the detailed explanation of the components except the different components will be omitted below.

Referring to FIG. 7A, a light emitting element in modification of the third embodiment is provided with the embedded part 150 composed of multiple embedded layers stacked. For example, a reflection preventing film 154 is formed on the concave portion 103b, and an embedded layer 156 is formed on the reflection preventing film 154. The reflection preventing film 154 is formed of, e.g., Si₃N₄. The reflection preventing film 154 is formed to have a thickness of λ/4n, where λ is a wavelength of light emitted from the active layer 105 and n is a refractive index of the material thereof, e.g., Si₃N₄. Where the embedded layer 156 is formed on the reflection preventing film 154 and the surface of the embedded layer 156 is flattened, the light emitting element in modification of the third embodiment can have high output and high reliability.

Referring to FIG. 7B, another light emitting element in modification of the third embodiment is provided with the embedded part 150 as composed below. First, a coated layer 158 is formed on the concave portion 103b by coating in such a thickness as to cover a part of the concave portion 103b or all of the concave portion 103b and the convex portion 103a. The coated layer 158 is formed of, e.g., SiO₂. In general, since the coated layer 158 is formed along the shape of the convex portion 103a by coating, the surface of the coated layer 158 becomes waved.

By repeating the coating process, the concavo-convex form can be gradually flattened. For example, when the coating material composing the coated layer 158 is coated on the n-type cladding layer 103, the coating material is embedded in the concave portions 103b and adhered to the tip portion of the convex portion 103a in a small thickness. Then, according as the coating process is repeated, the coating material is further embedded in the concave portion 103b so that the surface of the coated layer 158 can be gradually flattened by repeating the coating process. Thus, where a waved concavo-convex form is desired to be formed on the surface, the waved coated layer 158 can be formed by repeating multiple times the coating process.

Then, the embedded part 156 of SiO2 or Si3N4 excellent in crystalline quality is formed on the coated layer 158 by sputtering etc. Thereby, the embedded part 156 can prevent moisture etc. from externally penetrating into the n-type cladding layer 103 so that the light emitting elements in modification of the third embodiment can have high output and high reliability. According to the light emitting elements, the coated layer 158 has the waved surface or curved surface so that the light extraction efficiency can be enhanced by the lens effect.

### Fourth Embodiment

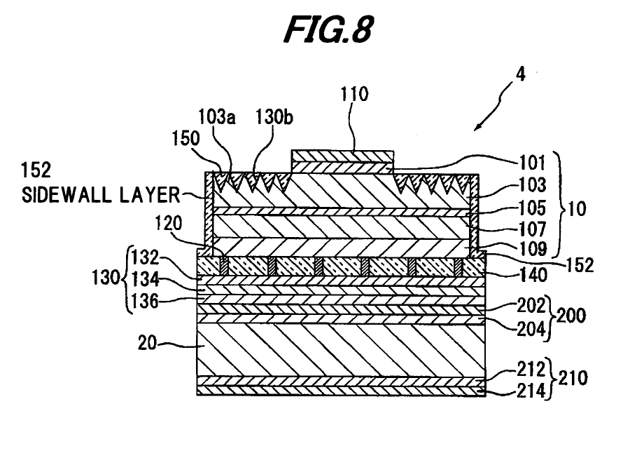

FIG. 8 is a schematic cross-sectional view showing a light emitting element in a fourth preferred embodiment according to the invention.

The light emitting element of the fourth embodiment has the same composition as the light emitting element 1 of the first embodiment except that a sidewall layer 152 is formed at least on the side face of the active layer 105. Thus, the detailed explanation of the components except the different components will be omitted below.

The light emitting element of the fourth embodiment is provided with the sidewall layer 152, which is formed of the same material as the embedded part 150, on the side face of the n-type cladding layer 103, the active layer 105, the p-type cladding layer 107 and the p-type contact layer 109. The sidewall layer 152 is formed of an insulating material.

For [example, the sidewall layer 152 is formed as below. First, in the fabrication method of the light emitting element 1 in the first embodiment, after the joined structure 1g is formed as shown in FIG. 2L, the element separation process as shown FIG. 2P is conducted by etching. Then, after the elements are separated from each other, the embedded part 150 is formed by conducting the same process as shown in FIGS. 2M and 2N. Here, in the fourth embodiment, after the elements are separated from each other, the side face of the n-type cladding layer 103, the active layer 105, the p-type cladding layer 107 and the p-type contact layer 109 is exposed. Therefore, in forming the embedded part 150, the sidewall layer 152 can be also formed on the side face of the n-type cladding layer 103, the active layer 105, the p-type cladding layer 107 and the p-type contact layer 109.

The light emitting element 4 of the fourth embodiment is provided with the sidewall layer 152 that is formed contacting the side face of the n-type cladding layer 103, the active layer 105, the p-type cladding layer 107 and the p-type contact layer 109. Thus, it can have an improved moisture resistance and a reduced leakage on the side face of the semiconductor stacked structure 10. Further, after the sidewall layer 152 is formed, the element (wafer) is diced into chips by the dicing equipment. During the dicing process by the dicing equipment, the side face of the semiconductor stacked structure 10 can be prevented from damaging and scrapes occurred in operating the dicing equipment can be prevented from adhering to the side face of the semiconductor stacked structure 10 which may cause a malfunction in characteristics of the light emitting element 4.

### EXAMPLES

According to the structure of the light emitting element 1 in the first embodiment, a light emitting element in Example is produced as below.

The semiconductor stacked structure is composed of the n-type cladding layer 103 of n-type AlGaInP, the active layer 105 in quantum well structure, and the p-type cladding layer 107 of p-type AlGaInP. The transparent layer 140 is formed of SiO₂. The contact part 120 is formed of AuBe. The reflecting layer 132 is formed of Au, the alloying suppression layer 134 is formed of Ti, and the joining layer 136 is formed of Au. Further, the joining layer 202 is formed of Au, and the contact electrode 204 is formed Al.

A conductive Si substrate with a thickness of 200 μm and low resistivity is used as the supporting substrate 20. The rear surface contact electrode 212 is formed of Al. The surface electrode 110 is formed of AuGe/Ni/Au and shaped like a circle with a diameter of 100 μm. The light emitting element in Example thus composed has a rectangular shape (top view) of 250 μm square and a thickness of about 200 μm.

The light emitting element in Example is mounted on a stem, and the surface electrode 110 is wire bonded to the current feeding portion of the stem. Then, it is sealed with silicone resin. Thus, as shown in FIG. 3, a light emitting device is produced. The following results are obtained in the characteristics evaluation of the light emitting device.

When forward current of 20 mA is fed, it exhibits an emission wavelength of 630 nm and an optical output of 27 mW to 30 mW. It has a forward voltage as low as 1.95 V.

### COMPARATIVE EXAMPLE

A light emitting element in Comparative Example is produced in which no embedded part 150 is formed in the concave portion 103b.

The light emitting elements in Example and Comparative example are tested in a thermal shock test between −40° C. to 150° C. and at 3000 cycles. As a result, even after the thermal shock test, the light emitting element in Example exhibits stably the same characteristics as before the test. By contrast, after the thermal shock test, the light emitting element in Comparative Example exhibits a reduced optical output of 10 mW to 20 mW and dispersed between the samples. As in the light emitting element in Comparative Example, the reduced and dispersed optical output is presumed to be caused by a breakage occurred in the convex portions due to the thermal shock.

Although the invention has been described with respect to the specific embodiments and Examples for complete and clear disclosure, the appended claims are not to be thus limited. In particular, it should be noted that all of the combinations of features as described in the embodiment and Examples are not always needed to solve the problem of the invention.

What is claimed is:

1. A light emitting element, comprising:
a semiconductor stacked structure comprising a first semiconductor layer of first conductivity type, a second semiconductor layer of second conductivity type different from the first conductivity type and an active layer sandwiched between the first semiconductor layer and the second semiconductor layer;
a plurality of convex portions formed on one surface of the semiconductor stacked structure; and
an embedded part for transmitting a light emitted from the active layer and reducing stress generated in the plurality of convex portions, the embedded part being formed between two adjacent convex portions of the plurality of convex portions.

2. The light emitting element according to claim 1, wherein the plurality of convex portions comprise a cross sectional structure that gradually narrows in a direction from the active layer to the one surface of the semiconductor stacked structure.

3. The light emitting element according to claim 2; wherein the embedded part comprises a material with a refractive index between that of the plurality of convex portions and that of a resin for covering the light emitting element.

4. The light emitting element according to claim 3, wherein the embedded part comprises a material with a linear expansion coefficient of not more than 1×10⁻⁵/K.

5. The light emitting element according to claim 4, wherein the plurality of convex portions comprise, in a cross section, a length of a horizontal part thereof along a horizontal plane parallel to the active layer is not more than a length of a height part thereof in a direction perpendicular to the horizontal plane.

6. The light emitting element according to claim 5, wherein the embedded part comprises a plurality of stacked materials with linear expansion coefficients different from each other.

7. The light emitting element according to claim 5, wherein the embedded part is formed to cover a tip portion of the plurality of convex portions.

8. The light emitting element according to claim 1, wherein the plurality of convex portions comprise a trapezoidal form in a cross section.

9. The light emitting element according to claim 1, wherein the semiconductor stacked structure further comprises a sidewall layer formed at least on a side face of the active layer.
